(19) United States
(12) Patent Application Publication
(10) Pub. No.: US 2011/0247677 A1
(43) Pub. Date: Oct. 13, 2011

(54) Temperature-controlled Photovoltaic Matrix and Method of Use

(76) Inventor: Eric Forsyth, Rutherford, NJ (US)

(21) Appl. No.: 12/759,033

(22) Filed: Apr. 13, 2010

(51) Int. Cl. H01L 31/052

(52) U.S. Cl. 136/246

(57) ABSTRACT

Embodiments of the disclosed technology comprise an exterior light focusing device, such as a parabolic cassegrain reflector connected via a fiber optic cable to an interior where beds or matrices of solar panels reside. The solar panels are positioned on sides of a light-disbursement device, such as a diffuser or series of mirrors/reflectors which receive an input of light from the optic cable and distribute it to solar panels/photovoltaic cells. The generated electrical energy from the solar panels may then be used to power a device, including the powering (charging) of a battery. Interior temperature of the photovoltaic cells as well as intensity and wavelength of light to the cells may be controlled. The solar panels may be constructed of materials without the need for consideration of weather resistance.

### FIELD OF THE DISCLOSED TECHNOLOGY

The disclosed technology relates generally to solar energy and, more specifically, to photovoltaic cells.

### BACKGROUND OF THE DISCLOSED TECHNOLOGY

Solar panels, or photovoltaic cells, convert light-energy into electrical energy. In general, for a given panel of photovoltaic cells, the total energy converted is proportionate to the number of photovoltaic cells receiving light-energy, such as from the sun. This is, of course, on the assumption that each photovoltaic cell is under the same conditions, i.e., is receiving the same amount of light, is the same distance away from an energy storage facility (e.g., battery), is at the same temperature, and so forth.

In practice, this results in at least four major problems, as described in greater detail herein below.

First, in practice photo voltaic arrays are limited by the amount of available space on which they can be mounted. Whether on a roof of a structure or an open field, at least one side must be exposed to a light source, typically, the sun. As is of course known, relative to a fixed point on the earth, the sun moves across the sky and is never facing any one direction. While the availability of space is not an obstacle in desolate places, it is desirable to use photovoltaic cells in population centers where power needs are greatest to avoid infrastructure costs, such as power lines, transformers, and so forth, as well as loss of power in the process of transporting it.

Second, placing photo-voltaic cells outdoors requires considerable extra expense in protecting such cells or panels of cells from the environment. They are exposed to wind, rain, snow, dust, debris, and the like, causing damage and efficiency/component loss.

Third, photovoltaic cells operate best within a certain range of temperatures. Some photovoltaic cells function better at lower temperatures, while some at higher. When outdoors and under the light of the sun, the photovoltaic cells heat up, often well above the ambient temperature and suffer from reduced efficiency with the increased temperature. Unfortunately, the higher temperatures are, by in large, associated with periods of time when input energy is at it's peak. That is, during the middle of the day when the sun is at it's highest, both the amount of energy to be harnessed from the sun and the amount of heat received are also typically at their highest, resulting in a great loss of efficiency.

Fourth, roof mounted applications of solar panels is complicated. Accessibility to roofs is often limited and installation requires proper securing of often heavy panels to the roof. This is labor intensive and a job not easily undertaking by an owner. Significant cost to transport and install the panels is required.

The prior art has attempted to solve the above-noted problems. For example, U.S. Pat. No. 4,026,267 to Coleman discloses a light-energy collecting device that receives light-energy (e.g., sunlight) into wide-angle lenses spread over a dwelling, and transfers the light-energy into a more controlled environment where a much smaller panel receives the light-energy. However, the large amount of paneling on the roof still takes up a great deal of real estate, and this system requires structural changes to a dwelling place. Further, the panels are exposed to the elements.

What is needed in the art of solar energy collection are devices and methods which are inexpensive to procure, maintain, and install, maximize efficiency of solar panels, and reduce the amount of space needed for their operation.

### SUMMARY OF THE DISCLOSED TECHNOLOGY

It is therefore an object of the disclosed technology to provide a photovoltaic system and devices thereof using the least amount of space possible, while obtaining maximized efficient use of solar energy and photovoltaic cells.

It is a further object of the disclosed technology to split solar energy by ranges of wavelengths for use with photovoltaic cells calibrated for such ranges.

It is a further object of the disclosed technology to provide a temperature-controlled environment, at temperatures which are most efficient for photovoltaic cells used in embodiments of the technology.

A device of the disclosed technology converts light-energy (that is, receives light) into electrical energy by way of a light focusing device, such as a parabolic reflector, operatively connected to a transmitting end of an optic cable, such as a fiber optic cable. A set of two spaced-apart panels of photovoltaic cells with a light-disbursement device, such as a diffuser or series of mirrors or other reflectors or a combination thereof, situated there-between is on a receiving end of the optic cable. That is, the light-disbursement device is operatively connected to the optic cable. The device is operative to convert at least some of the light-energy entering the light focusing device into electrical energy, to power an electrically operated device or electrical sink (device which is using energy or taking in more energy than it is generating), including—but not limited to—charging a battery for later use of the energy.

In embodiments of the device of the disclosed technology, a matrix of panels with light-disbursement devices is used and may be connected (by way of splitting the light based on wavelength and/or intensity) to an optic cable. For purposes of embodiments of the disclosure, any material change to the light on the receiving end of the optic cable is considered to be part of the light-disbursement device, and the device, as a whole, may be partially or fully situated between panels of photovoltaic cells (“solar panels”). The matrix of panels, is, for example, at least ten sets of two spaced apart panels with a light-disbursement device situated partially or fully there-between. At least two different sets of the two spaced-apart panels are separated by, and in contact with, an insulation layer in embodiments of the technology. The insulation layer is also a rigid structural layer in embodiments of the disclosed technology, adding stability to the matrix of photovoltaic cells.

In embodiments of the disclosed technology, the photovoltaic cells are placed in a thermally controlled environment such as a heated or air-cooled environment and/or kept at or near (within 5 degrees) a constant temperature. Thus, the parabolic reflector or other light collecting device is exposed to the environment and the photovoltaic cells are located in a thermally regulated environment.

The light-disbursement device may be a light diffuser, mirrors, refractory mirrors, prisms (which, for purposes of this disclosure are considered a mirror as a prism comprising features of a mirror), or other devices known in the art. The light-disbursement device may separate light according to ranges of wavelengths and, in some cases, a majority of received light is reflected at a 90 degree angle to the photovoltaic cells for maximum efficiency. To achieve this, the light-disbursement device may have a plurality of mirrors at a 45 degree angle to a direction of travel of light-energy emitted from an optic cable, and the light-disbursement device reflects the light-energy at a right angle into at least one photovoltaic cell. The light-energy may be emitted at, at least two opposite sides of the set of two spaced-apart panels and each mirror of the plurality of mirrors reflects a different beam of light exiting from the optic cable.

A method for converting light-energy into electrical energy is carried out in embodiments of the disclosed technology by receiving light into a light-focusing device operatively connected to a transmitting end of an optic cable. Then, by way of a light-disbursement device, a set of two spaced-apart panels of photovoltaic cells is operatively connected on either side of the light-disbursement device to a receiving end of an optic cable. Electrical energy is then used to power or charge a separate device.

Further aspects of the device of the disclosed technology described above are also applicable to methods of the disclosed technology.

### BRIEF DESCRIPTION OF THE DRAWINGS

FIG. 1 shows a high level diagram of devices used in embodiments of the disclosed technology.

FIG. 2 shows an elevation view of a matrix of diffusers and photovoltaic cells used in embodiments of the disclosed technology.

FIG. 3 shows a perspective view of a matrix of diffusers and photovoltaic cells with optical cables attached thereto.

FIG. 4 shows a plan view of a diffuser used in embodiments of the disclosed technology.

FIG. 5 shows a perspective view of a diffuser with optical cables attached thereto, as used in embodiments of the disclosed technology.

FIG. 6 shows an elevation view of a matrix of photovoltaic cells with electrical connectors, insulation, and diffusers used in embodiments of the disclosed technology.

FIG. 7 shows a top-side perspective view of a photovoltaic cell with electrical connectors used in embodiments of the disclosed technology.

FIG. 8 shows a side view of the matrix of FIG. 6 with serial electrical connections between panels, and the path of light into diffusers.

FIG. 9 shows a side view of the matrix of FIG. 6 with parallel electrical connections between panels, and the path of light into diffusers.

FIG. 10 shows a cutaway side view of angled and selectively mirrored plates disposed between photovoltaic cells in a further embodiment of the disclosed technology.

FIG. 11 shows a magnified version of Inset A of FIG. 10.

### DETAILED DESCRIPTION OF EMBODIMENTS OF THE DISCLOSED TECHNOLOGY

Described on a high level, embodiments of the disclosed technology comprise an exterior light focusing device, such as a cassegrain dish reflector connected via a fiber optic cable to an interior where beds or matrices of solar panels reside. A cassegrain dish is a form of parabolic reflector, as is known in the art. The solar panels are positioned on sides of a light-disbursement device (a device which disperses or modifies the intensity/wavelength of a beam of light into a plurality of beams of light), such as a diffuser or series of mirrors/reflectors which receive an input of light from the optic cable and distribute it to solar panels/photovoltaic cells. The generated electrical energy from the solar panels may then be used to power a device, including the powering (charging) of a battery. As the solar panels are indoors and may be layered or in a matrix, the amount of exterior real estate required is minimal per unit of panel, and the light reaching solar panels is controlled in embodiments of the disclosed technology, such as the intensity on each solar panel or wavelength, to maximize efficiency. Temperature may also be controlled.

Embodiments of the disclosed technology will become clear in light of the following description of the figures.

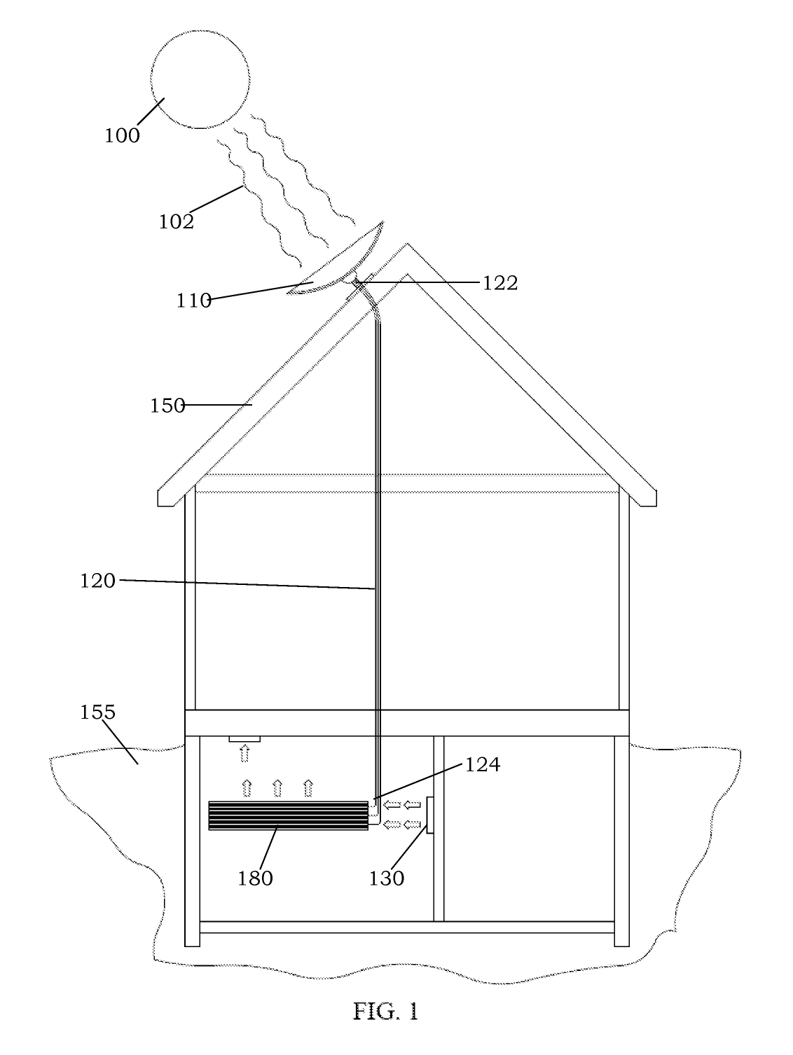

FIG. 1 shows a high level diagram of devices used in embodiments of the disclosed technology. Light source 100, here the sun, radiates light-energy 102 towards a light focusing device 110, here a parabolic reflector as is known in the art, and reflects light into a concentrated area. Optic cable 120 is operatively connected to the light focusing device 110 at a transmitting end 122 thereof. As shown in FIG. 1, the light focusing device 110 in embodiments of the disclosed technology is at and/or receives light at an external or outdoor location. The transmitting end of the optic cable 122 transmits the collected light-energy to a receiving end 124 of the optic cable located, in embodiments of the disclosed technology, in an interior space which may be temperature controlled, such as by way of air conditioner 130 which propagates cold air into the interior space 150 or a subset (e.g., a room or container) thereof. Temperature may further be regulated by placing the receiving end 124 of the optic cable 120 underground 155. A matrix 180 of photovoltaic cells and light-disbursement devices are situated in the interior space 150 or an above-described subset thereof. The matrix 180 will be described in greater detail in the following figures.

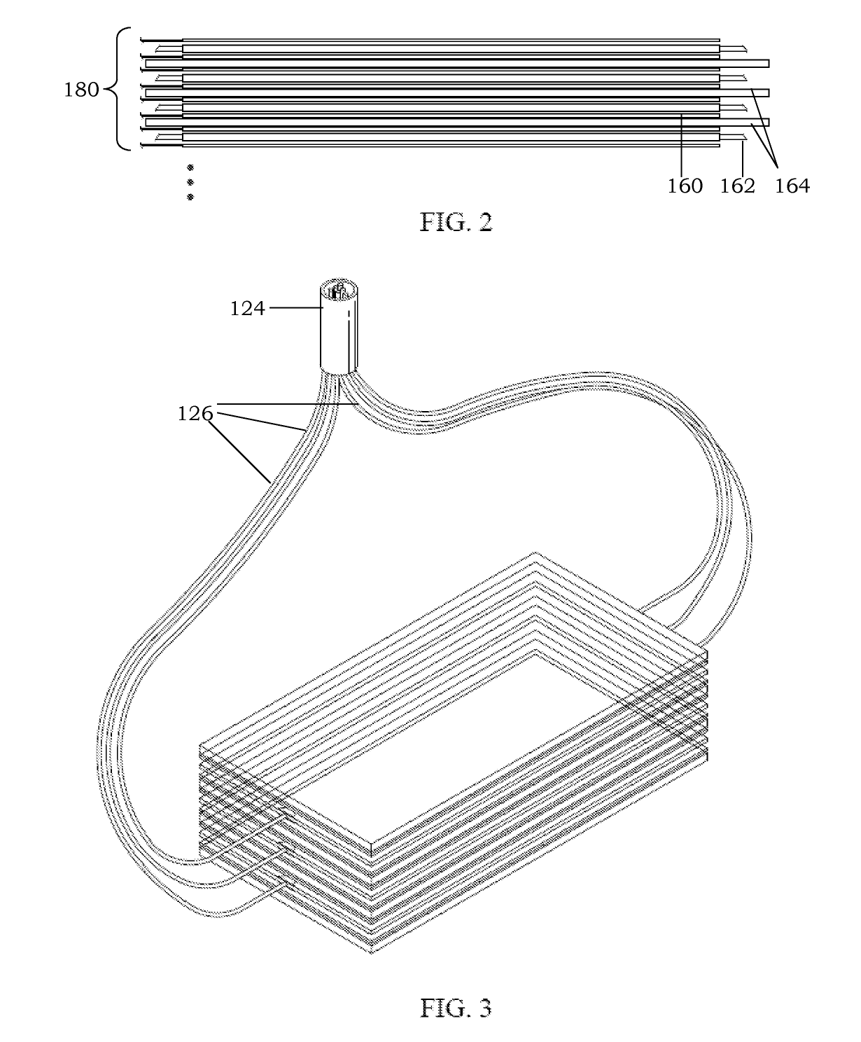

FIG. 2 shows an elevation view of a matrix of diffusers and photovoltaic cells used in embodiments of the disclosed technology. FIG. 3 shows a perspective view of a matrix of diffusers and photovoltaic cells with optical cables attached thereto. For purposes of this disclosure, a matrix is defined as at least ten panels of photovoltaic cells with a light-disbursement device situated between at least two panels. Referring first to FIG. 3, a receiving end 124 of an optic cable 120 is operatively connected to one or a plurality of light-disbursement devices 162. The receiving end 124 of the optic cable 120 and/or the light-disbursement device may comprise a plurality of individual fiber optic links 126 which extend into the matrix directly, or by way of an operative connection, to a light-disbursement device between two panels of photovoltaic cells 160. Insulation 164, in embodiments of the disclosed technology, such as shown in FIG. 2, is placed between two successive panels of photovoltaic cells. As such, referring now in particular to FIG. 2 and embodiments of the disclosed technology, the items shown in FIG. 2 are layered in the following order: solar panel 160|light-disbursement device 162|solar panel 160|insulation layer 164|solar panel 160|light-disbursement device 162|etc. In this manner, the photovoltaic cells of a solar panel always face towards a light-disbursement device, and an insulation layer, when placed, is situated between two successive solar panels.

The insulation layer 164, in embodiments of the disclosed technology, is rigid and provides structural support to a matrix or any grouping of spaced apart solar panels. The layer may be contiguous with insulation layers of other parts of the matrix, or may extend only the length of a solar panel on either side of it or up to 10% more. The insulation and structural qualities may vary based on material used. For example, it may be desirable, in an embodiment, to have very strong structural features (such as with a very large matrix or grouping of matrices of solar panels) and use a metal mesh, while requiring little insulation (to save on cost). On the other hand, both a strong structure and high insulation may be required, and so foam or fiberglass insulation, by way of example, may be used with a matrix mesh, and so forth.

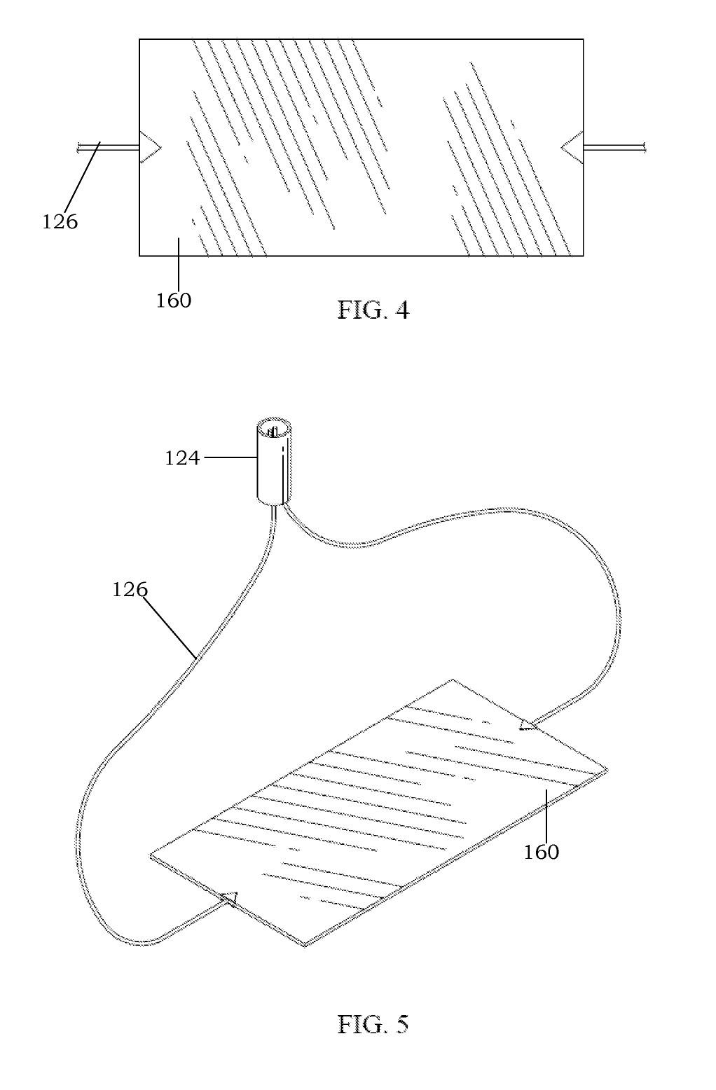

FIG. 4 shows a plan view of a diffuser used in embodiments of the disclosed technology. FIG. 5 shows a perspective view of a diffuser with optical cables attached thereto as used in embodiments of the disclosed technology. A diffuser is a type of light-disbursement device 162. The diffuser may be any device that diffuses or spreads out or scatters light, such as a ground glass diffuser, teflon diffuser, holographic diffuser, opal glass diffuser, or grey-glass diffuser. Light is received via a receiving end 126 of an optic cable 120 and at one or both ends of a diffuser, as shown in FIGS. 4 and 5, where it is then deflected, at least in part, towards and through the generally elongated flat sides of the diffuser towards photovoltaic cells.

The diffuser may be a standalone light-disbursement device or may be part of a larger light-disbursement device beginning at the receiving end of the optic cable 124 or 126. In embodiments of the disclosed technology, each diffuser, light-disbursement device, or part thereof receives only particular wavelengths of light. For example, a single diffuser or single matrix may receive only infrared light or another red light, while another receives green, another blue, and another ultraviolet. The light may be split into wavelengths by a preliminary filter spaced between the light-focusing device 110 and the light-disbursement device 162 at any point, or be part of the light-disbursement device 162. In this manner, the photovoltaic cells can be calibrated and/or more efficient for a particular wavelength or set of wavelengths of light, and the appropriate wavelengths are sent to the appropriate cells.

In a similar manner, diffusers and mechanisms for separating light (e.g., prisms, mirrors, etc.) may be used to split beams of light based on intensity. For example, for purposes of cost efficiency, it may be desired to use photovoltaic cells which, in a panel, are optimized for 1000 lux of light. In embodiments of the disclosed technology, a desired or optimal lux of light (in addition to, or instead of, a desired or optimal range of wavelengths) may be delivered to individual photovoltaic cells, panels, and/or diffusers. Thus, for example, where the lux exiting from an optic cable 120 is high, e.g., 10,000 lux, it may be split 10 ways and delivered to photovoltaic cells that work optimally with 1000 lux. Similarly, this may be combined with splitting the incoming light by wavelength. A photovoltaic cell operating best with ultraviolet light at 1000 lux may receive exactly that, given the same input, and the remaining 9000 lux may go to other solar panels. Even more so, for efficiency, when the amount of incoming lux is lower, e.g., on a cloudy day or near nightfall, to maximize efficiency, certain light pathways/light-disbursement devices may be disabled, shutoff, or blocked with a polished mirror, or the like, so as to most efficiently use the received light on fewer solar panels, while maintaining or raising the intensity of the light compared to a situation when all available panels are utilized.

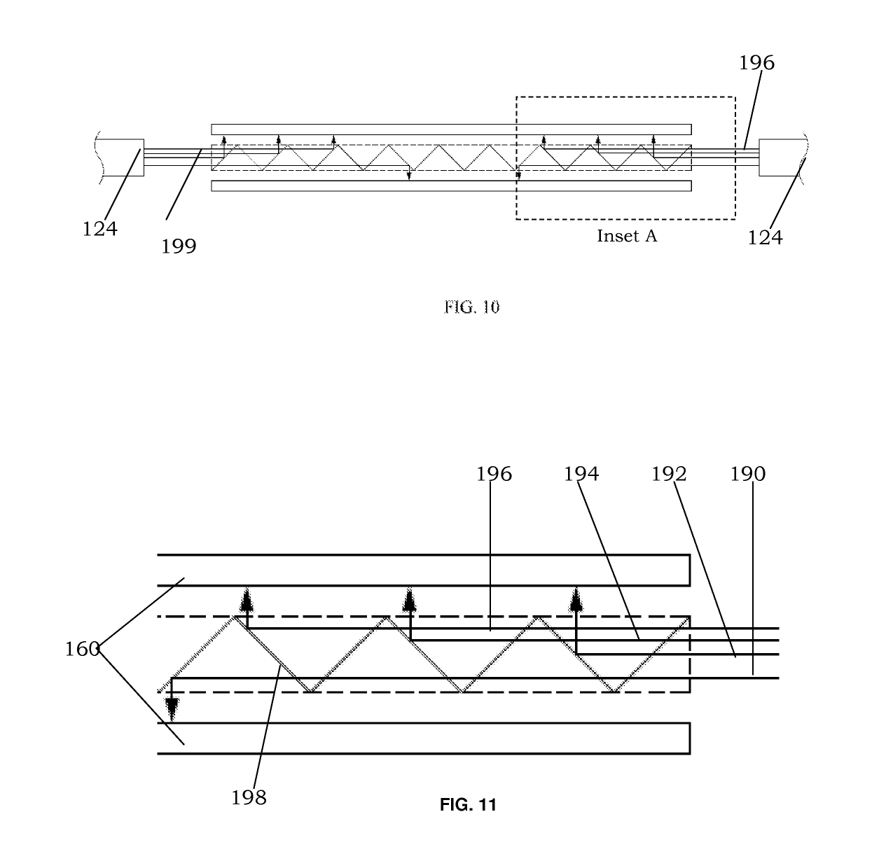

Skipping now to FIGS. 10 and 11, which show other light-disbursement devices, FIG. 10 shows a cutaway side view of angled and selectively mirrored plates disposed between photovoltaic cells in a further embodiment of the disclosed technology. FIG. 11 shows a magnified version of Inset A of FIG. 10. A receiving end of a fiber optic cable 124, which in embodiments of the disclosed technology may comprise a light-disbursement device, accurately aims beams of light 190, 192, 194, 196, 199, and so forth at a particular section of an angled mirror 198. As shown in the figures, the angled mirror 198 is a succession of mirrors at a 45 degree angle to the angle of incidence of incoming light and also a 45 degree angle to the elongated surface of solar panels and photovoltaic cells 160, in embodiments of the disclosed technology. Each mirror may reflect only light above or below a certain wavelength (e.g., a prism), allowing remaining light to pass through to the next angled part of the mirror, etc.

Light hitting one side of any two portions of the mirror which meet at a vertex will be reflected either up or down, while light hitting the other portion of the mirror sharing the vertex will be reflected in the opposite direction. The embodiment shown in FIGS. 10 and 11 may also be viewed in three dimensions, where each segment of the mirror is at a different position relative to the Z axis of the plane of the paper on which the Figure is shown, and the incoming beams of light, 190, 192, 194, and 196, for example, may each be at a different point on the Z-axis (one in front of the other) so as to hit different parts of the mirror and thus be reflected upwards or downwards at different points and hit different photovoltaic cells. As is shown in FIG. 10, light may enter from a receiving end 124 of an optic cable at either or both ends, and a single mirror section or segment (defined as a generally elongated piece of mirror having at least partial reflective properties and situated between two vertices may reflect light entering from more than one side.

Still referring to FIGS. 10 and 11, the embodiment shown may be used to maximize power gain and is an improvement over the prior art, where solar panels often receive light at whatever angle it happens to be coming in at the moment, or must be turned to face the light source. Here, while a light collector 100 may be turned to face a light source, the energy cost of doing so is slight compared to moving solar panels and, in this embodiment, the solar panels need not be physically moved, while maximum efficiency due to the angle of incidence is achieved because the incoming light-energy is directed primarily normal to (at a right angle to) a length of photovoltaic cells. That is, the light is delivered to and aimed directly into the cells, irrespective of the angle of the sun and without moving the solar panels themselves.

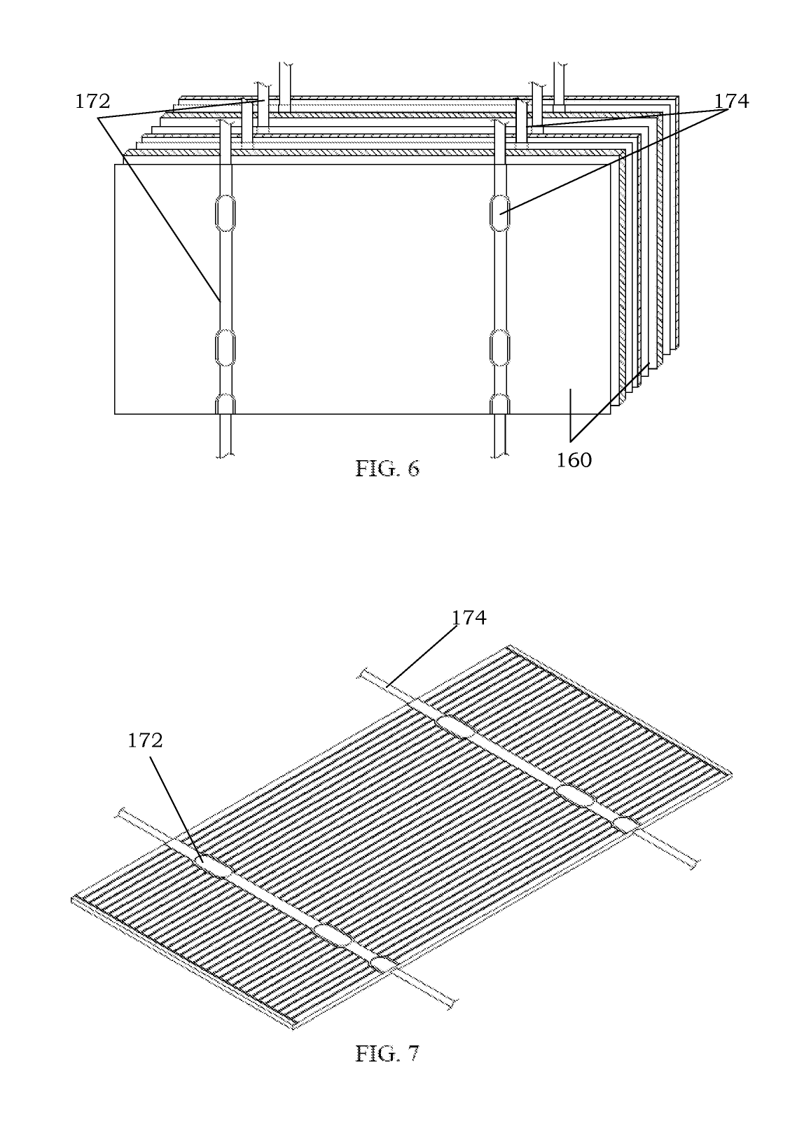

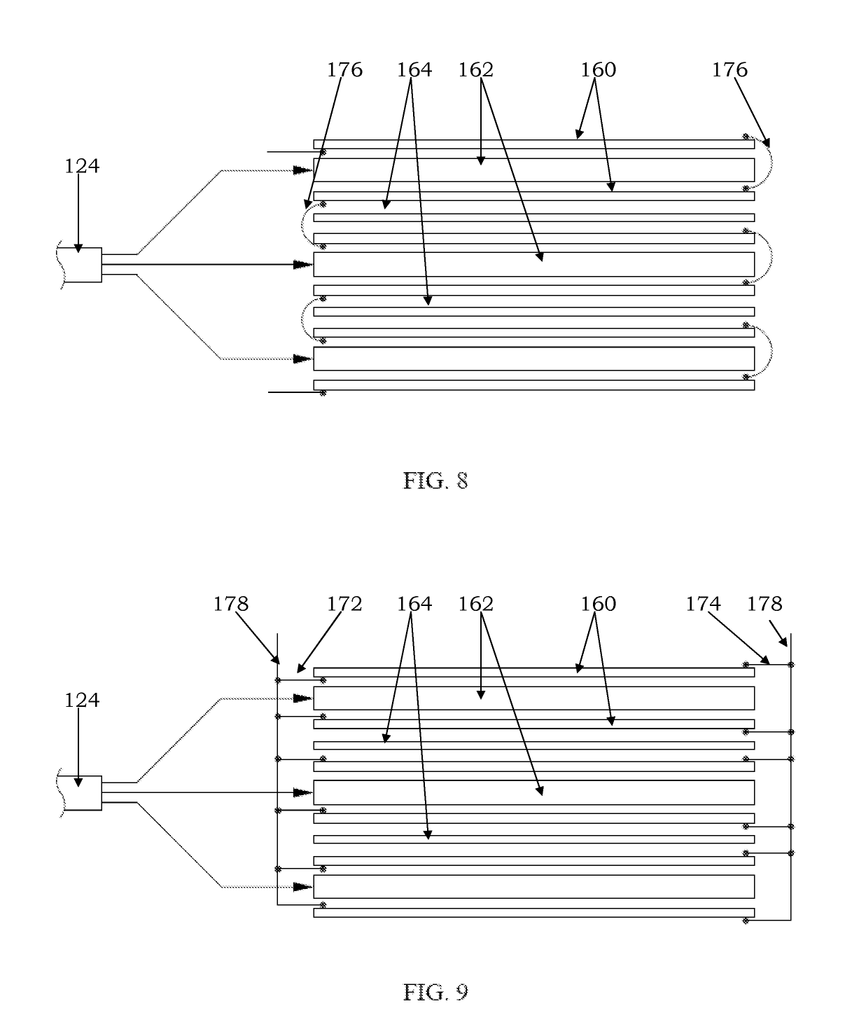

Referring back to FIG. 6, this figure shows an elevation view of a matrix of photovoltaic cells with electrical connectors, insulation, and diffusers used in embodiments of the disclosed technology. FIG. 7 shows a top-side perspective view of a photovoltaic cell with electrical connectors used in embodiments of the disclosed technology. FIG. 6 is similar to that of FIG. 2, from a different angle and showing electrical connections 172 and 174 on each solar panel 160/panel of photovoltaic cells. It should be understood that the electrical connectors and conduits shown are by way of example and any number or configurations of electrical connectors and conduits can be used. FIGS. 6 and 7 show the electrical connectors 172 and 174 which emanate from each panel. FIGS. 8 and 9 show connections between panels.

FIG. 8 shows a side view of the matrix of FIG. 6 with serial electrical connections between panels, and the path of light into diffusers. FIG. 9 shows a side view of the matrix of FIG. 6 with parallel electrical connections between panels, and the path of light into diffusers. In these figures, the configuration of the layers 160, 162, and 164 is seen, as well as the path of light emanating from a receiving end of an optic cable 124. In FIG. 8, electrical connections 176 attach to each successive solar panel 160 on alternating sides to form a serial (series) circuit. In FIG. 9, each electrical connection 172 and 174 of the solar panels 160 attaches to a wire 178 to form a parallel circuit. Each configuration may be used, depending on the needs of a particular embodiment, or, in some embodiments, some parallel circuitry and some series circuitry is used.

It should also be understood that the matrices of photovoltaic cells and light-disbursement devices may be placed, in embodiments of the disclosed technology, into larger arrays. Thus, a matrix comprising photovoltaic cells and light-disbursement devices may be placed next to or alongside a second, third, and/or fourth matrix, etc, in series or parallel. Each matrix internally may be wired in series or parallel. Twelve, twenty, one hundred, or one hundred and forty-four matrices may be electrically connected in an array, and each matrix may be turned on (light directed to light-disbursement devices within the matrix) or turned off (light blocked from entry into the light-disbursement device) based on needs of the embodiment, including wavelength and intensity of the incoming light vs. wavelength and intensity calibration/peak energy conversion of photovoltaic cells within each matrix.

While the disclosed technology has been taught with specific reference to the above embodiments, a person having ordinary skill in the art will recognize that changes can be made in form and detail without departing from the spirit and the scope of the disclosed technology. The described embodiments are to be considered in all respects only as illustrative and not restrictive. All changes that come within the meaning and range of equivalency of the claims are to be embraced within their scope. Combinations of any of the methods, systems, and devices described hereinabove are also contemplated and within the scope of the invention.

I claim:

1. A light-energy collecting device comprising:
a light-focusing device operatively connected to a transmitting end of an optic cable;
a set of two spaced-apart panels of photovoltaic cells comprising a light-disbursement device situated there-between; and
a receiving end of said optic cable operatively connected to said light-disbursement device;
wherein said device is operative to convert at least some of said light-energy entering said light-focusing device into electrical energy.

2. The light-energy collecting device of claim 1, wherein at least ten said sets of two spaced-apart panels are operatively connected to said receiving end of said optic cable.

3. The light-energy collecting device of claim 2, wherein at least two different said sets of two spaced-apart panels are separated by and in contact with an insulation layer.

4. The light-energy collecting device of claim 1, wherein said light-focusing device comprises a parabolic reflector.

5. The light-energy collecting device of claim 4, wherein said parabolic reflector is exposed to the environment and said photovoltaic cells are located in a thermally regulated environment.

6. The light-energy collecting device of claim 1, wherein said light-disbursement device is a filter.

7. The light-energy collecting device of claim 1, wherein said light-disbursement device separates light by wavelength.

8. The light-energy collecting device of claim 7, wherein said light-disbursement device reflects a majority of received light at a 90 degree angle to said photovoltaic cells.

9. The light-energy collecting device of claim 1, wherein said light-disbursement device comprises a plurality of mirrors at a 45 degree angle to a direction of travel of light-energy emitted from a said optic cable and said light-disbursement device reflects said light-energy at a right angle into at least one said photovoltaic cell.

10. The light-energy collecting device of claim 9, wherein said light-energy is emitted at, at least two opposite sides of said set of said two spaced-apart panels, and each mirror of said plurality of mirrors reflects a different beam of light exiting from said optic cable.

11. A method for converting light-energy into electrical energy comprising:
receiving light into a light-focusing device operatively connected to a transmitting end of an optic cable;
by way of a light-disbursement device, operatively connecting a set of two spaced-apart panels of photovoltaic cells positioned on either side of said light-disbursement device to a receiving end of an optic cable; and
using electrical energy to power or charge a separate device.

12. The method of claim 11, wherein at least ten said sets of two spaced-apart panels are operatively connected to said receiving end of said optic cable.

13. The method claim 12, wherein at least two different said sets of two spaced-apart panels are separated by and in contact with an insulation layer.

14. The method of claim 11, wherein said light-focusing device comprises a parabolic reflector.

15. The method of claim 14, wherein said parabolic reflector is exposed to the environment and said photovoltaic cells are located in a thermally regulated environment.

16. The method of claim 11, wherein said light-disbursement device is a diffuser.

17. The method of claim 11, wherein said light-disbursement device separates light by wavelength.

18. The method of claim 17, wherein said light-disbursement device reflects a majority of received light at a 90 degree angle to said photovoltaic cells.

19. The method of claim 11, wherein said light-disbursement device comprises a plurality of mirrors at a 45 degree angle to a direction of travel of light-energy emitted from a said optic cable, and said light-disbursement device reflects said light-energy at a right angle into at least one said photovoltaic.

20. The method of claim 19, wherein said light-energy is emitted at least two opposite sides of said set of said two spaced-apart panels and each mirror of said plurality of mirrors reflects a different beam of light exiting from said optic cable.
